(19) United States
(12) Patent Application Publication
(10) Pub. No.: US 2026/0358411 A1
(43) Pub. Date: Nov. 12, 2026

(54) OPTICAL PROBE AND POSITIONING TECHNIQUES BASED ON ANALYSIS OF CAVITY-INDUCED REFLECTION SPECTRA

(71) Applicant: EXFO INC., Quebec (CA)

(72) Inventors: Sammy NOEL PARISE, Quebec (CA); Raphael DUBE-DEMERS, Quebec (CA); Antoine GERVAIS, Quebec (CA)

(21) Appl. No.: 19/632,891

(22) Filed: Mar. 30, 2026

Related U.S. Application Data
(60) Provisional application No. 63/802,265, filed on May 8, 2025.
(60) Provisional application No. 63/824,411, filed on Jun. 16, 2025.

(51) Int. Cl. G01R 31/311

(52) U.S. Cl. CPC G01R 31/311

(57) ABSTRACT

The disclosure relates to systems and methods for determining and adjusting the position of an optical probe relative to an optical device under test (DUT), such as a photonic integrated circuit, by analyzing reflection spectra generated from an optical cavity formed at least partially in the gap between the probe and the DUT. Light injected through the probe toward the DUT reflects within the cavity and produces interference patterns in the reflection spectrum, which are analyzed to determine the probe's separation distance and angular orientation. This positional information may be used to adjust the probe's position for proper alignment. The disclosure also provides an optical probe incorporating separate optical channels for positioning and measurement. The positioning channels leverage cavity-induced interference to enable probe alignment, while the measurement channels are designed to avoid such interference during optical testing. Both channel types may be implemented using optical fibers or other guided-wave structures.

### CROSS-REFERENCE TO RELATED APPLICATIONS

This application claims priority under 35 U.S.C. § 119(e) to U.S. Provisional Patent Application Ser. No. 63/802,265, filed on May 8, 2025, and U.S. Provisional Patent Application Ser. No. 63/824,411, filed on Jun. 16, 2025, both of which are incorporated herein in their entireties by reference.

### TECHNICAL FIELD

The technical field pertains to alignment systems and methods in optical testing, and more specifically, to an optical testing probe and related positioning techniques based on the analysis of cavity-induced reflection spectra.

### BACKGROUND

Photonic integrated circuits (PICs) are microchips that integrate multiple photonic components onto a common substrate for processing and transmitting information. They are increasingly used in applications such as telecommunications, sensing, and data processing, offering compact and scalable solutions. However, the complexity of testing and packaging processes continues to contribute to production costs, creating a need for accurate and high-throughput testing methods to support broader adoption.

Automated testing stations are commonly used to characterize PIC performance by injecting light into, and collecting light from, a PIC device under test using optical probes (e.g., fiber arrays) and integrated optical couplers. Two primary coupling approaches are employed in PIC testing: surface coupling, where light is introduced out-of-plane through the PIC's top surface, and edge coupling, where light is introduced in-plane through the side of the PIC. Edge coupling is often preferred due to its higher efficiency and lower polarization sensitivity.

However, edge coupling requires precise alignment, as even small translational or angular deviations can significantly impact coupling efficiency and measurement repeatability. This challenge is particularly notable in systems with multi-channel probes, where angular misalignments can introduce cumulative positional errors across channels. As a result, there remains a need for alignment strategies in PIC testing that provide sufficient precision and reliability, while also offering scalability and compatibility with wafer-level or high-throughput environments where maintaining consistent probe positioning is challenging.

### SUMMARY

The present disclosure concerns systems and methods for determining and adjusting the position of an optical probe relative to an optical device under test (DUT) by analyzing reflection signals generated from an optical cavity extending at least partially in the gap between the probe and the DUT. Light delivered to the DUT through the probe reflects within the cavity and is detected as a reflection spectrum featuring interference patterns, which arise from reflections at different interfaces of the cavity. These patterns are analyzed to extract positional information, including the separation distance and angular orientation of the probe relative to the DUT. Based on this information, the position of the probe can be adjusted to achieve appropriate positioning.

The present description also relates to an optical testing probe including one or more dedicated positioning channels located at known spatial offsets relative to one or more measurement channels within the same probe body. Using the disclosed position determination method, reference signals obtained from the positioning channels are used to determine the position of the positioning channels relative to the DUT, enabling accurate positioning of the measurement channels based on the known offsets.

The disclosed techniques are applicable to a range of optical devices and testing scenarios, including but not limited to the characterization of photonic integrated circuits (PICs), in both edge- and surface-coupled configurations.

In accordance with an aspect, there is provided a method for determining a positional relationship between an optical probe and an optical device under test (DUT), the method including:
positioning the optical probe relative to the DUT with a separation distance therebetween, the separation distance spanning at least a portion of an optical cavity formed between the optical probe and the DUT, the optical cavity including multiple optical interfaces;
delivering probe light to the DUT via the optical probe;
collecting probe light reflected from the optical cavity via the optical probe;
detecting the collected return light to obtain a reflection spectrum including interference patterns resulting from reflections at the multiple optical interfaces of the optical cavity; and
analyzing the reflection spectrum to determine the separation distance based on the interference patterns.

In some embodiments, the DUT includes a photonic integrated circuit.

In some embodiments, the optical probe includes one or more optical fibers.

In some embodiments, positioning the optical probe relative to the DUT includes coupling the optical probe to the DUT in an edge-coupled configuration. In other embodiments, wherein positioning the optical probe relative to the DUT includes coupling the optical probe to the DUT in a surface-coupled configuration.

In some embodiments, the reflection spectrum is acquired within a wavelength range from about 1260 nm to about 1680 nm.

In some embodiments, the probe light is generated using a wavelength-swept light source. In other embodiments, the probe light is generated using a broadband light source.

In some embodiments, analyzing the reflection spectrum includes: extracting a free spectral range (FSR) parameter from the reflection spectrum; and determining the separation distance based on the FSR parameter.

In some embodiments, analyzing the reflection spectrum includes applying a model or using calibration data relating reflection spectrum features to known separation distances.

In some embodiments, analyzing the reflection spectrum includes modeling the optical cavity as a two-interface structure, the multiple optical interfaces including: a probe-side interface between the optical probe and a separation medium between the optical probe and the DUT; and a DUT-side interface between the DUT and the separation medium. In some embodiments, the probe-side interface and the DUT-side interface each include a silica-air interface.

In some embodiments, analyzing the reflection spectrum includes modeling the optical cavity as an N-interface structure, with N>2, the multiple optical interfaces including: a probe-side interface between the optical probe and a separation medium between the optical probe and the DUT; a DUT-side interface between the DUT and the separation medium; and at least one internal optical interface within the DUT. In some embodiments, the probe-side interface and the DUT-side interface each include a silica-air interface, and the at least one internal interface includes a silica-silicon interface.

In some embodiments, the optical probe includes a set of optical channels having known positional offsets therebetween, and the method further includes:
performing the delivering, collecting, detecting, and analyzing steps for each of the optical channels to obtain a corresponding set of separation distances; and
determining an angular position of the optical probe relative to the DUT based on the set of separation distances and the known positional offsets.

In some embodiments, the DUT is arranged on a planar substrate, the set of separation distances extending substantially parallel to the planar substrate, and the angular position being defined with respect to a rotation axis substantially perpendicular to the planar substrate.

In accordance with another aspect, there is provided a method for positional adjustment between an optical probe and an optical device under test (DUT), the method including:
providing a target positional relationship between the optical probe and the DUT; and
performing a positional adjustment operation including one or more iterative cycles, each iterative cycle including:
   determining, using the method as disclosed herein, a current positional relationship between the optical probe and the DUT;
   comparing the current positional relationship with the target positional relationship; and
   where a mismatch exists between the current and target positional relationships, adjusting the current positional relationship to reduce the mismatch and initiating another iterative cycle; otherwise, terminating the positional adjustment operation.

In some embodiments, the target positional relationship includes a target separation distance and/or a target angular orientation of the optical probe relative to the DUT.

In accordance with another aspect, there is provided a system for determining probe positioning relative to optical device under test (DUT), the system including:
a light source configured to generate probe light;
an optical probe configured to be positioned relative to the DUT with a separation distance therebetween, the separation distance spanning at least a portion of an optical cavity formed between the optical probe and the DUT, the optical cavity including multiple optical interfaces, the optical probe being configured to couple the probe light from the light source into the DUT and to collect return light reflected from the optical cavity;
an optical detector configured to detect the collected return light as a reflection spectrum including interference patterns resulting from reflections at the multiple optical interfaces of the optical cavity; and
a control and processing unit coupled to the optical detector and configured to analyze the reflection spectrum to determine the separation distance based on the interference patterns.

In some embodiments, the light source includes a wavelength-swept light source. In other embodiments, the light source includes a broadband light source.

In some embodiments, the optical probe includes one or more optical fibers.

In some embodiments, the optical probe is configured to couple with the DUT in an edge-coupled configuration. In other embodiments, the optical probe is configured to couple with the DUT in a surface-coupled configuration.

In some embodiments, the optical probe includes a set of optical channels having known positional offsets therebetween, the light source and the optical detector are configured to acquire, through each optical channel, a corresponding one of a set of reflection spectra, and the control and processing unit is configured to: analyze the set of reflection spectra to determine a corresponding set of separation distance; and determine an angular position of the optical probe relative to the DUT based on the set of separation distances and the known positional offsets

In accordance with another aspect, there is provided an optical probe for testing an optical device under test (DUT), the optical probe including:
at least one positioning channel configured to form an optical cavity with the DUT upon coupling therewith, the optical cavity generating interference patterns in a reflection spectrum acquired by illuminating the DUT via the at least one positioning channel, the interference patterns being indicative of a positional relationship between the at least one positioning channel and the DUT; and
at least one measurement channel positioned at a specified offset relative to the at least one positioning channel, the at least one measurement channel being configured to couple with the DUT with reduced optical cavity formation relative to the at least one positioning channel, the specified offset enabling positioning of the at least one measurement channel relative to the DUT based on the positional relationship conveyed by the interference patterns.

In some embodiments, the at least one positioning channel and the at least one measurement channel each include an optical fiber or an optical fiber array.

In some embodiments, the optical probe is configured for surface coupling with the DUT, the at least one positioning channel including an optical fiber with a substantially flat end face, and the at least one measurement channel including an optical fiber with an angled or anti-reflective-coated end face.

In some embodiments, the optical probe is configured for edge coupling with the DUT, the at least one positioning channel including an optical fiber oriented substantially parallel to a coupling edge of the DUT, the at least one measurement channel including an optical fiber oriented obliquely relative to the coupling edge, and the optical probe further including at least one reflective structure positioned to redirect light between the DUT and both the positioning and measurement channels.

In some embodiments, the at least one measurement channel includes an array of measurement channels arranged along a measurement axis, and the at least one positioning channel includes one or more first positioning channels disposed at one end of the array of measurement channels and one or more second positioning channels disposed at the other end of the array of the measurement channels.

In some embodiments, the one or more first positioning channels and the one or more second positioning channels include an array of first positioning channels and an array of second positioning channels, each array aligned along a positioning axis that is substantially perpendicular to the measurement axis.

In some embodiments, the array of measurement channels consists of four measurement channels, the array of first positioning channels consists of two first positioning channels, and the array of second positioning channels consists of two second positioning channels.

In accordance with another aspect, there is provided a system for testing an optical device under test (DUT), the system including:
an optical probe including a plurality of optical channels, the plurality of optical channels including:
   at least one positioning channel configured to form an optical cavity with the DUT upon coupling therewith and to generate interference patterns in a reflection spectrum indicative of a positional relationship between the at least one positioning channel and the DUT; and
   at least one measurement channel positioned at a specified offset relative to the at least one positioning channel and configured to couple with the DUT with reduced optical cavity formation relative to the at least one positioning channel;
a light source configured to deliver light to the DUT via the optical probe;
an optical detector configured to detect return light from the DUT via the optical probe;
a positioning assembly configured to adjust a relative position between the optical probe and the DUT; and
a control and processing unit operatively coupled to the optical detector and the probe positioning unit,
wherein the system is operable in:
   a positioning mode, wherein the light source and the optical detector are used to acquire the reflection spectrum via the at least one positioning channel, and the control and processing unit is configured to: determine the positional relationship based on the interference patterns, and controls the positioning assembly to bring the at least one measurement channel into a measurement position relative to the DUT based on the determined positional relationship and the specified offset; and
   a measurement mode, wherein the light source and the optical detector are used to perform optical testing of the DUT via the at least one measurement channel.

In some embodiments, the control and processing unit is configured to determine, as the positional relationship, either or both of: a separation distance between the at least one positioning channel and the DUT; and an angular position of the optical probe relative to the DUT.

In accordance with another aspect, there is provided a method for positioning an optical probe relative to an optical device under test (DUT), the method including:
providing an optical probe including a positioning channel and a measurement channel, the measurement channel being positioned at a specified offset relative to the positioning channel;
injecting light into the positioning channel, the positioning channel forming an optical cavity with the DUT upon coupling therewith, the optical cavity including multiple optical interfaces;
acquiring, in response to the injected light, a reflection spectrum including interference patterns resulting from reflections at the multiple optical interfaces of the optical cavity;
analyzing the reflection spectrum to determine a positional relationship between the positioning channel and the DUT based on the interference patterns; and
adjusting the optical probe to bring the measurement channel into a measurement position relative to the DUT based on the determined positional relationship and the specified offset.

In accordance with another aspect, there is provided a method for testing an optical device under test (DUT), the method including:
providing an optical probe including a positioning channel and a measurement channel, the measurement channel positioned at a specified offset relative to the positioning channel;
performing a positioning operation including:
injecting light into the positioning channel, the positioning channel forming an optical cavity with the DUT upon coupling therewith, the optical cavity including multiple optical interfaces;
acquiring, in response to the injected light, a reflection spectrum including interference patterns resulting from reflections at the multiple optical interfaces of the optical cavity;
analyzing the reflection spectrum to determine a positional relationship between the positioning channel and the DUT based on the interference patterns; and
adjusting the optical probe to bring the measurement channel into a measurement position relative to the DUT based on the determined positional relationship and the specified offset; and
performing a measurement operation including injecting light into and collecting light from the DUT via the measurement channel.

Other method and process steps may be performed before, during, or after the steps described herein. The order of one or more steps may also differ, and some of the steps may be omitted, repeated, or combined, as the case may be. It is also noted that some steps may be performed using various analysis and processing techniques, which may be implemented in hardware, software, firmware, or any combination thereof.

Other objects, features, and advantages of the present techniques will become more apparent upon reading of the following non-limiting description of specific embodiments thereof, given by way of example only with reference to the appended drawings. Although specific features described in the above summary and in the detailed description below may be described with respect to specific embodiments or aspects, it should be noted that these specific features may be combined with one another unless stated otherwise.

### BRIEF DESCRIPTION OF THE DRAWINGS

FIGS. 1 to 15 depict various aspects, features, and implementations of, or related to, the techniques disclosed herein.

FIG. 1 is a flow diagram of a method for determining a positional relationship between an optical probe and an optical device under test (DUT), in accordance with an embodiment.

FIG. 2 is a schematic representation of a system for testing a photonic integrated circuit (PIC), in accordance with an embodiment.

FIG. 3 illustrates an example measured reflection spectrum exhibiting Fabry-Pérot interference patterns generated by the cavity between an optical probe and a DUT. These spectral features enable extraction of the free spectral range (FSR) and estimation of the probe-to-DUT axial separation distance.

FIG. 4 illustrates the probe-to-DUT separation distances extracted from a series of twelve optical return loss (ORL) measurements acquired at 400-nm incremental probe displacements. A linear fit to the estimated values yields a standard deviation of 0.21 μm, indicating submicron resolution.

FIG. 5 illustrates variations in the axial separation distances measured across the probe's optical channels resulting from probe rotation about an axis perpendicular to the PIC surface, enabling estimation of the probe's in-plane tilt angle.

FIG. 6 illustrates how the measured axial separation distances for different probe channels vary with channel offset, enabling computation of the probe's in-plane tilt angle from the slope of the best-fit line.

FIG. 7 illustrates the comparison between tilt angles derived from cavity length measurements and known reference angles, with the linear fit demonstrating the accuracy of the cavity-based in-plane angular estimation.

FIG. 8 is a flow diagram of a method 300 for positional adjustment between an optical probe and an optical DUT, in accordance with an embodiment.

FIG. 9 illustrates a surface-coupled configuration in which a probe with a vertically oriented optical channel forms a three-interface cavity with a multilayered PIC, producing a reflection spectrum with interference patterns enabling extraction of the probe-PIC separation distance.

FIG. 10 illustrates a simulated reflection spectrum for a vertical-incidence surface-coupled probe-to-PIC configuration, showing interference features arising from the three-interface cavity formed by the probe, air gap, and PIC layers, which enable extraction of the probe-to-PIC separation distance.

FIG. 11 is a schematic representation of a system for testing a PIC, in accordance with an embodiment, in which the system incorporates an optical probe having separate positioning channels for probe alignment and measurement channels for PIC testing.

FIG. 12 is a schematic representation of an optical probe having separate positioning channels for probe alignment and measurement channels for PIC testing, in accordance with an embodiment.

FIG. 13 is a schematic representation of an edge-coupled optical probe having separate positioning and measurement channels with reflective structures directing light to and from the PIC edge, in accordance with an embodiment.

FIG. 14 illustrates a side elevation view of one of the positioning channels of the edge-coupled optical probe shown in FIG. 13, which includes a vertically oriented optical fiber and a reflective structure configured to couple light normally to the PIC edge and form an optical cavity.

FIG. 15 illustrates a side elevation view of one of the measurement channels of the edge-coupled optical probe shown in FIG. 13, which includes an obliquely oriented optical fiber and a reflective structure configured to couple light normally to the PIC edge while suppressing cavity formation.

### DETAILED DESCRIPTION

The present disclosure describes systems and methods for determining and adjusting the position of an optical probe relative to an optical device under test (DUT) by analyzing reflection signals generated within an optical cavity formed in the gap between the probe and the DUT. The disclosure further introduces an optical testing probe incorporating both positioning and measurement optical channels. The positioning channels leverage cavity-induced interference effects for precise position determination, while the measurement channels are configured to reduce or suppress such effects during optical testing. Both channel types may be implemented using optical fibers or other guided-wave structures.

Testing and characterizing photonic integrated circuits (PICs) typically involves a combination of optical, electrical, and optoelectronic measurements, with optical probes playing a central role in coupling light into and out of the DUT. High positioning precision is generally required to ensure optimal measurement efficiency, accuracy, and repeatability. In many testing environments, the DUT is mounted on a motorized stage that provides controlled motion along multiple translational axes, as well as rotation about one or more axes, enabling coarse and fine placement of the PIC. Optical and electrical probes are likewise mounted on motion units that may provide up to six degrees of freedom (translation along three orthogonal axes, and rotation about each of these axes) to allow accurate alignment of the probes relative to the DUT for testing operations.

One relevant application of the disclosed techniques is the alignment of optical probes to photonic integrated circuits (PICs), particularly in wafer-level or automated testing environments where high-throughput, repeatable measurements are important. Probes for PIC testing, whether used in edge- or surface-coupled configurations, commonly employ optical fiber arrays to interface simultaneously with multiple input and output waveguides on the PIC and to streamline the alignment process. Typically, these arrays employ single-mode fibers with a beam radius of approximately 10 μm, operating at wavelengths between about 1.2 μm and 1.7 μm. As a result, submicron alignment accuracy, generally within an order of magnitude below the beam radius, is often required. Fiber pitch within the arrays commonly ranges from about 20 μm to 250 μm, enabling precise lateral placement over the PIC's optical interfaces. Angular alignment is also important, as even slight angular deviations can lead to significant coupling losses due to the elongated geometry of the array relative to the optical mode size.

Existing alignment approaches for PIC testing often rely on machine-vision systems, optical power monitoring, or external sensors. These techniques are typically constrained by diffraction-limited resolution, a lack of mechanisms for continuous nanoscale adjustment, sensitivity to positional drift, and variability among probes. Furthermore, many existing methods lack closed-loop feedback, particularly for angular alignment. Consequently, conventional techniques often fail to deliver consistent submicron precision or to maintain stable alignment over time, limiting scalability and repeatability in both research and manufacturing environments.

To address these limitations, the present disclosure introduces a method that uses cavity-based interference effects to infer probe position with enhanced precision. These effects arise from reflections at the interfaces between the probe, the intermediate gap, and the DUT. The method employs a wavelength-swept or broadband light source in conjunction with an optical detector to direct probe light onto, and collect return light from, the DUT through the probe's positioning channels. By analyzing interference patterns in the reflection spectrum, the system can determine the optical path length across the gap and thereby infer the relative separation and angular orientation of the probe with respect to the DUT. Because the spatial relationship between the positioning and measurement channels is known, the system can adjust the probe to bring the measurement channels into proper alignment, while reducing cavity effects within the measurement paths. These techniques are compatible with a variety of optical testing platforms and can be adapted to different device types, probe configurations, and test environments.

Additional aspects and example implementations are described below with reference to the accompanying figures.

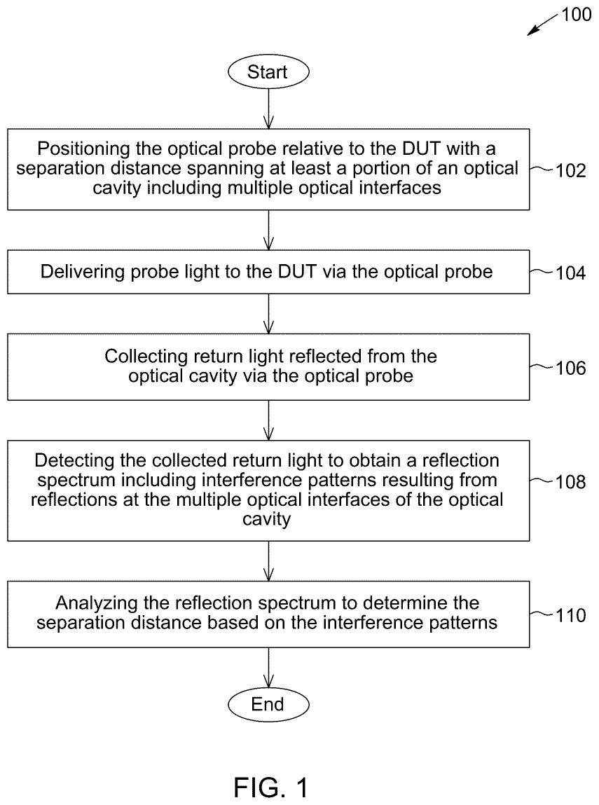

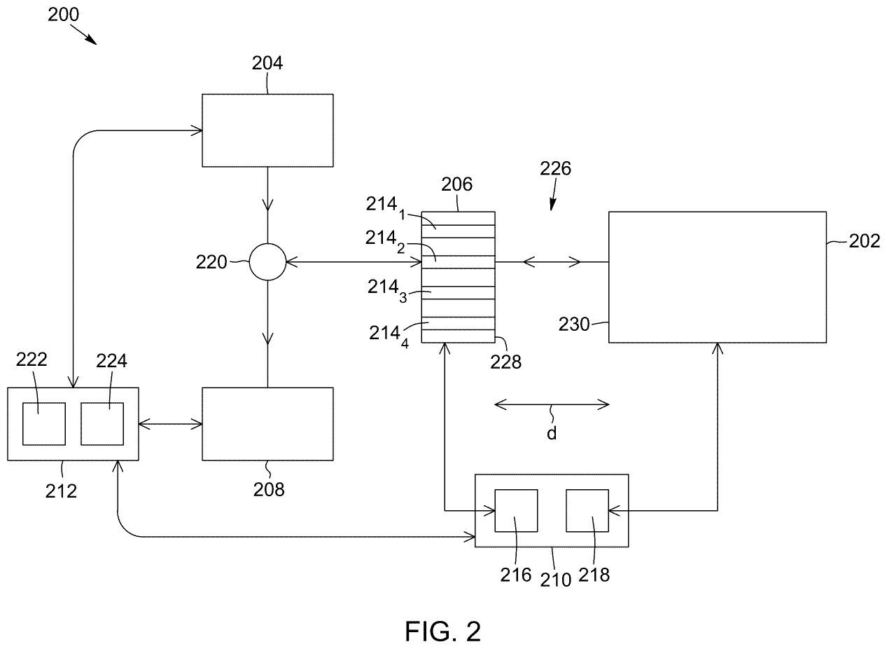

FIG. 1 illustrates a flow diagram of a method 100 for determining a positional relationship between an optical probe and an optical DUT using interference effects arising from an optical cavity that includes the gap between them. As detailed below, the method 100 involves directing probe light via the probe toward the DUT, collecting return light through the probe, and processing the resulting reflection spectrum to extract information such as the separation distance and angular orientation between the probe and the DUT. The method 100 may be implemented using a testing system 200 such as the one depicted in FIG. 2.

The system 200 is configured for optical testing and positional determination relative to an optical DUT 202. In the illustrated embodiment, the DUT 202 is a PIC and is referenced as such below, although the disclosed techniques are applicable to a broad range of optical devices and test configurations, including planar lightwave circuits and distributed feedback lasers. The system 200 includes a light source 204, an optical probe 206, an optical detector 208, a positioning assembly 210, and a control and processing unit 212. These components may be integrated into a standalone instrument or assembled in modular form, with hybrid configurations also contemplated. Further details regarding the configuration and operation of these components are provided below. It should be noted that FIG. 2 is a schematic representation intended to highlight functional and structural aspects of the testing system 200. For clarity, certain auxiliary features or practical implementation details, such as those found in full testing stations, have been simplified or omitted.

FIG. 2 illustrates the system 200 configured for edge coupling to the PIC 202. However, the disclosed techniques are also applicable to surface-coupled configurations under appropriate conditions, such as with grating couplers that support normal-incidence coupling and can induce cavity interference effects. The PIC 202 may include various interconnected photonic components, such as waveguides, splitters, combiners, modulators, interferometers, switches, and integrated sources and detectors. The PIC 202 may be fabricated on platforms including silicon-on-insulator, indium phosphide, silicon nitride, lithium niobate, or gallium arsenide. The system 200 may be used to characterize PICs in formats including full wafers, wafer bars, and single- or multi-die configurations.

The light source 204 may be any device capable of generating light suitable for PIC testing, which may include both narrowband and broadband types. In some embodiments, the light can have a bandwidth lying within a range from about 1260 nm to about 1680 nm (e.g., encompassing the O, E, S, C, L, and U telecommunication wavelength bands in the short-wavelength infrared). However, this spectral range is illustrative, as the disclosed techniques are also applicable across the visible, near-infrared, and mid-infrared spectra. In some embodiments, the light source 204 is a laser source, such as a high-power continuous-wave tunable laser with narrow linewidth and high-resolution tunability. Examples of laser types include solid-state lasers (e.g., fiber lasers, bulk crystal lasers) and semiconductor lasers (e.g., laser diodes). Non-laser sources are also contemplated, including light-emitting diodes (LEDs), amplified spontaneous emission (ASE) sources, and semiconductor optical amplifiers (SOAs). Conditioning optics such as filters, lenses, and amplifiers may be used to tailor the light before delivery to the PIC 202.

The optical probe 206 enables bidirectional optical coupling with the PIC 202. In some embodiments, the probe 206 includes an optical fiber array configured for alignment with edge couplers of the PIC 202. The fiber array may include any suitable number of single- or multimode fibers (e.g., 2, 4, 8, or 16), used for light delivery, collection, or both. In the illustrated embodiment, the probe 206 includes a linear array of four optical channels 214₁-214₄. However, both the number of channels and their spatial arrangement may be varied depending on the application. Fiber parameters such as composition, geometry, refractive index profile, numerical aperture, polarization handling, and spectral compatibility may be customized to suit specific performance criteria. While fiber arrays are commonly used, alternative implementations employing other types of optical waveguides or couplers, such as photo-inscribed or free-form waveguides, are also contemplated.

The optical detector 208 may include any photodetector capable of measuring optical power in the relevant spectral range. Examples include PIN photodiodes, avalanche photodiodes, and Schottky photodiodes. Selection of a suitable detector may be based on parameters such as power levels, spectral range, sensitivity, and response time. In some embodiments, the optical detector 208 may be a non-spectrally resolved detector (e.g., an optical power meter) used in combination with a wavelength-swept light source (e.g., a tunable laser) to reconstruct the spectral response of the PIC 202. In other embodiments, the optical detector 208 may be a spectrally resolved detector (e.g., an optical spectrum analyzer (OSA) or a swept-wavelength system) used together with a broadband light source (e.g., a superluminescent LED (SLED) or ASE source) to acquire the PIC's spectral response.

The positioning assembly 210 enables precise control over the relative position between the PIC 202 and the probe 206. It may include a probe positioning unit 216, a PIC positioning unit 218, or both, each providing independent actuation and supporting translation and/or rotation with respect to one or multiple axes. Step sizes may reach submicron levels (e.g., 100 nm or less). Actuation mechanisms may include piezoelectric stages, stepper motors, or voice coil drives. The positioning assembly 210 may accommodate different PIC formats and support both manual and automated control.

The control and processing unit 212 is operatively coupled to various system components, including the light source 204, optical detector 208, and positioning assembly 210. It may include one or more processors 222 and one or more memories 224, implemented in hardware, software, firmware, or combinations thereof. The control and processing unit 212 may be partially or fully integrated with other system components or implemented as a separate module. Beyond signal processing (e.g., interpreting detector output to extract positioning information), the control and processing unit 212 may coordinate various system operations, including light source and positioning assembly control. The control and processing unit 212 may support wired or wireless communication with system components and may be operated through direct user input and/or programmed instructions. The control and processing unit 212 may interact with user interfaces provided with input and output devices (e.g., touchscreens, buttons, displays) and may utilize distributed or cloud-based computing resources for data processing or storage.

As illustrated in FIG. 2, an optical Fabry-Perot (FP) cavity 226 is formed between the probe 206 and the PIC 202. This cavity 226 is defined by two partially reflective surfaces: a probe-side interface 228 (e.g., a fiber facet) and a PIC-side interface 230 (e.g., a PIC surface). The physical gap between these interfaces 228, 230, typically filled with air, defines the cavity length and induces interference patterns in the reflected light due to multiple internal reflections. These patterns are sensitive to changes in cavity length and can be analyzed to infer the separation distance between the two interfaces 228, 230. Because this distance is measured along the axis of optical propagation, from the probe facet to the PIC surface, it may also be referred to as the axial separation distance.

In some embodiments, optical return loss (ORL) measurements are used to acquire the reflection spectrum of the cavity 226, which may be modeled as:

$$R = \frac{{R}_{1} + {R}_{2} - 2 \sqrt{{R}_{1} {R}_{2}} cos δ}{1 + {R}_{1} {R}_{2} - 2 \sqrt{{R}_{1} {R}_{2}} cos δ} , \qquad ( 1 )$$

where R₁ and R₂ are the Fresnel reflection coefficients of the probe-side and PIC-side interfaces 228, 230, respectively, and 8 is the round-trip optical phase shift experienced by light traveling through the cavity 226. For normal incidence, the phase shift 8 is given by:

$$δ = \frac{4 π nd}{λ} , \qquad ( 2 )$$

where n is the refractive index of the medium (typically n~1 for air), d is the cavity length (i.e., the axial probe-PIC separation), and λ is the free-space wavelength. As the reflection spectrum R(λ) exhibits interference patterns whose characteristics depend on cavity length, analyzing these spectral features enables accurate estimation of the separation distance d between the probe 206 and the PIC 202. Using this technique, certain embodiments can achieve submicron precision with standard optical test instrumentation.

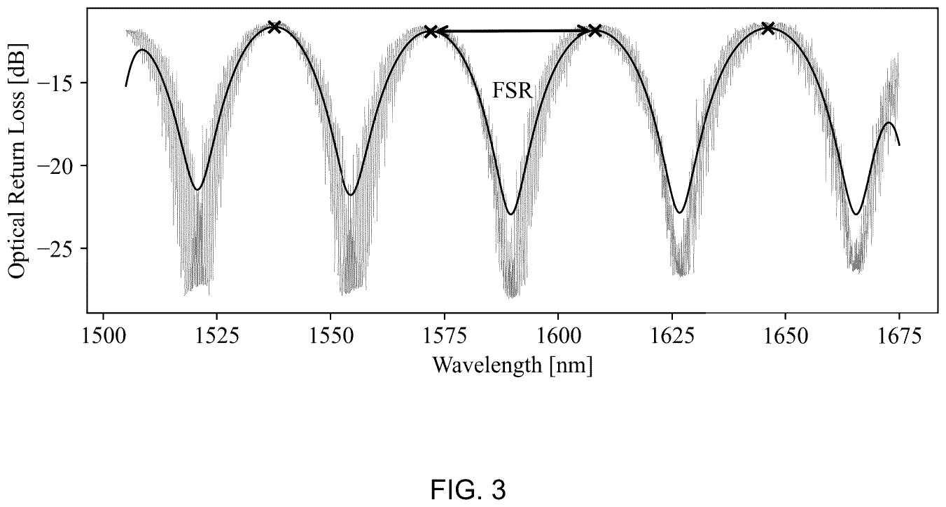

As illustrated in FIG. 1, and with reference to FIG. 2, the method 100 begins by positioning the optical probe 206 at an initial separation distance from the PIC 202 (step 102). This initial separation may be coarsely estimated or unknown. Step 102 may be performed by the probe positioning unit 216. In step 104, probe light from a light source 204, either broadband or wavelength-tunable, is injected into the probe 206 and directed toward the PIC 202. Reflected light is collected via the probe 206 (step 106) and measured by an optical detector 208 (step 108), producing a reflection spectrum R(λ) that exhibits interference patterns generated by the optical cavity 226. A circulator 220 or equivalent routing element (e.g., optical splitter or switch) may be used to direct the forward-propagating signal from the source 204 to the probe 206 and to route the backward-propagating signal from the probe 206 to the detector 208. FIG. 3 shows a representative reflection spectrum measured over a 170 nm range (1505-1675 nm). Other wavelength bands may be used depending on the application, whether within or outside the previously mentioned 1260-1680 nm range.

In step 110, the reflection spectrum R(λ) is analyzed to determine the cavity length. Modeling the optical cavity as a two-interface FP structure, with a probe-side interface 228 between the optical probe 206 and the separation medium, and a PIC-side interface 230 between the PIC 202 and the separation medium, the free spectral range (FSR), given by λ²/2nd, is extracted from the interference fringes and used to compute the axial separation distance d. In FIG. 3, the extracted FSR is overlaid on the measured spectrum to illustrate the model's fit. Techniques such as fringe spacing analysis, peak detection, curve fitting, global optimization, or Fourier-based decomposition may be used to extract the FSR or other suitable spectral parameters, thereby improving the robustness and accuracy of the distance estimation.

It is noted that the method 100 does not require alignment of the probe 206 with optical couplers or other input ports of the PIC 202, as the light from the source 204 need not be coupled into the PIC 202 for testing or characterization. Rather, it is sufficient for the probe light to reflect off the PIC surface to form the cavity 226, producing interference features in the reflection spectrum R(λ) from which positional information can be extracted.

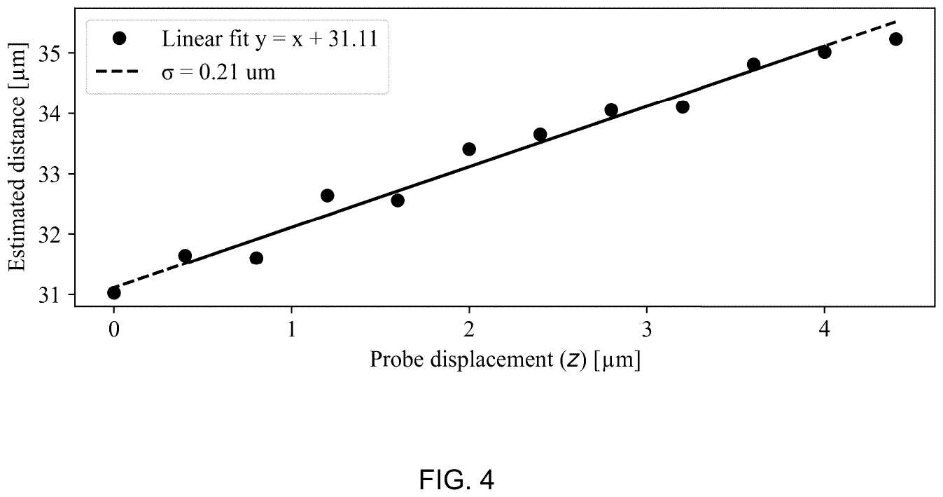

The accuracy of the method 100 is demonstrated in FIG. 4. A series of ORL spectra was acquired while incrementally displacing the probe by 400 nm between each of twelve steps, for a cumulative displacement of 4.4 μm. The method 100 was applied at each step to estimate the separation distance. The estimated values are plotted against the applied displacements, and a linear fit yielded a standard deviation of 0.21 μm, indicating submicron resolution. Additional testing confirmed effectiveness up to separation distances of at least 500 μm.

Returning to FIGS. 1 and 2, in some embodiments, the method 100 also enables estimation of the in-plane angular orientation of the probe 206 relative to the PIC 202. This feature may be useful when the probe 206 includes multiple optical channels 214₁-214₄. Angular estimation is achieved by repeating steps 104 through 110 for each optical channel. Combining the resulting set of cavity lengths with the known lateral offsets between the channels enables accurate estimation of the probe's angular orientation.

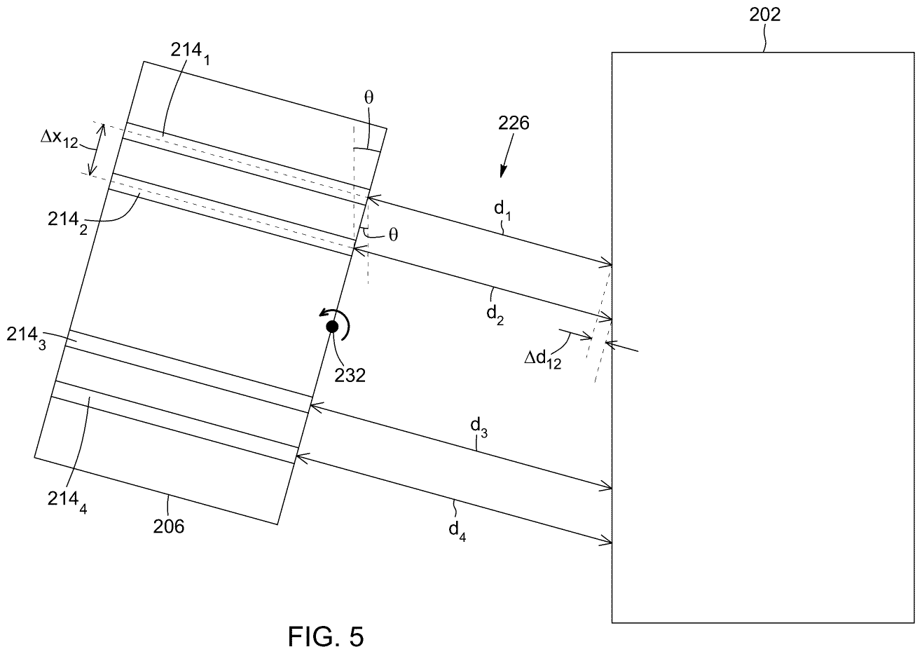

FIG. 5 illustrates how probe rotation about an axis 232 perpendicular to the PIC's planar substrate causes variations in the axial separation distances d₁, d₂, d₃, d₄ across the probe's channels 214₁-214₄. Because the channels 214₁-214₄ are laterally offset by known distances (e.g., Δx₁₂, Δx₂₃, etc.), any angular tilt introduces systematic, measurable differences in the resulting cavity lengths. These variations can be determined to compute the in-plane tilt angle θ of the probe 206. For two channels separated by Δx₁₂ with measured cavity lengths d₁ and d₂, the tilt angle may be approximated by:

$$θ = arctan ( \frac{{d}_{2} - {d}_{1}}{Δ {x}_{12}} ) . \qquad ( 3 )$$

For small angles, this simplifies to θ~(d₂−d₁)/Δx₁₂=Δd₁₂/Δx₁₂. For N channels, plotting the measured separations {d₁, d₂, . . . , d_{N}} against the known lateral offsets and computing the slope of the best-fit line yield the tilt angle θ.

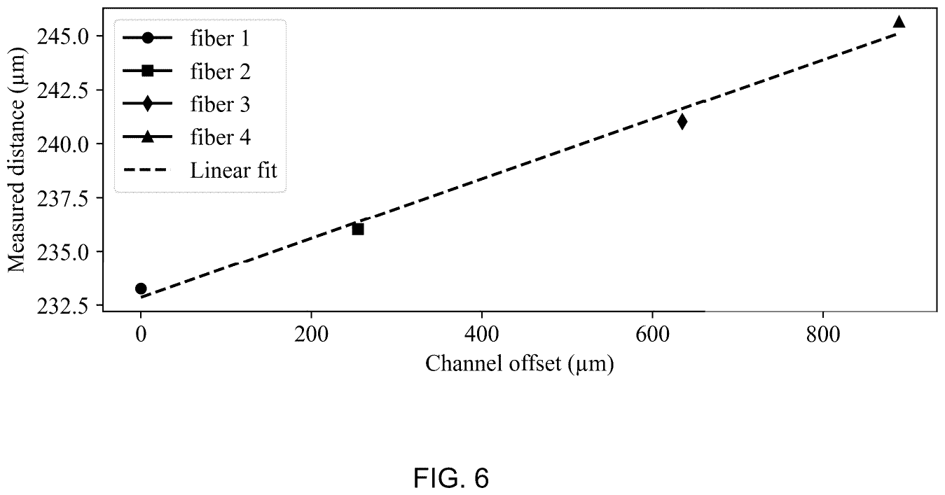

FIG. 6 demonstrates this principle using measured data from four channels. The results show a generally linear behavior, confirming the method's ability to estimate angular orientation from cavity length measurements. Optimal angular alignment is achieved when the slope of the plot of the separation distance versus lateral offset approaches zero, indicating that the probe facet is parallel to the PIC surface and all channels have equal axial separation.

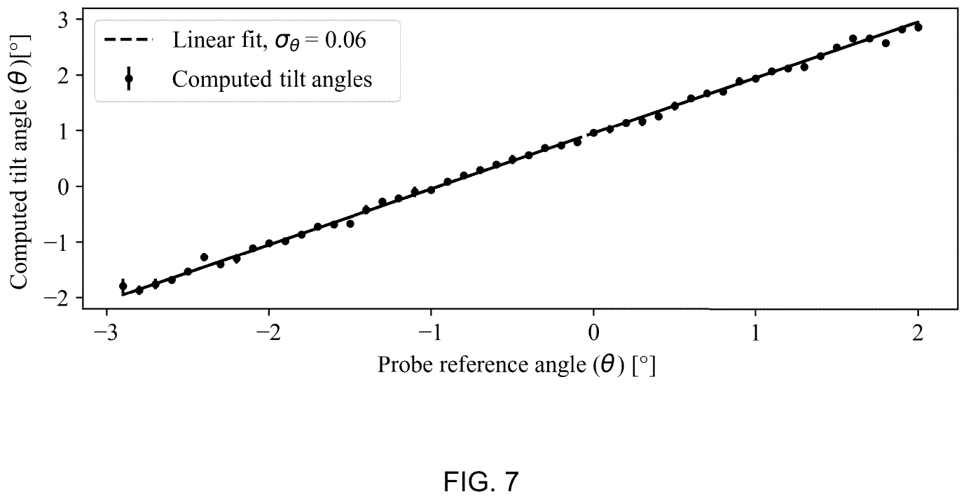

FIG. 7 further validates the method by comparing tilt angles computed from cavity length measurements with known reference angles from the probe positioning unit. A linear fit yielded a standard deviation of 0.06°. While equal cavity lengths across all channels may not correspond precisely with the zero reference of the positioning unit (due to reference frame offsets), the method supports precise relative angular alignment to optimize optical coupling. Various analytical techniques can also be employed to estimate the position of the rotation axis, further improving alignment accuracy.

Once both the axial and angular positions are determined, the probe's alignment can be refined through an iterative, feedback-controlled adjustment process, as described below.

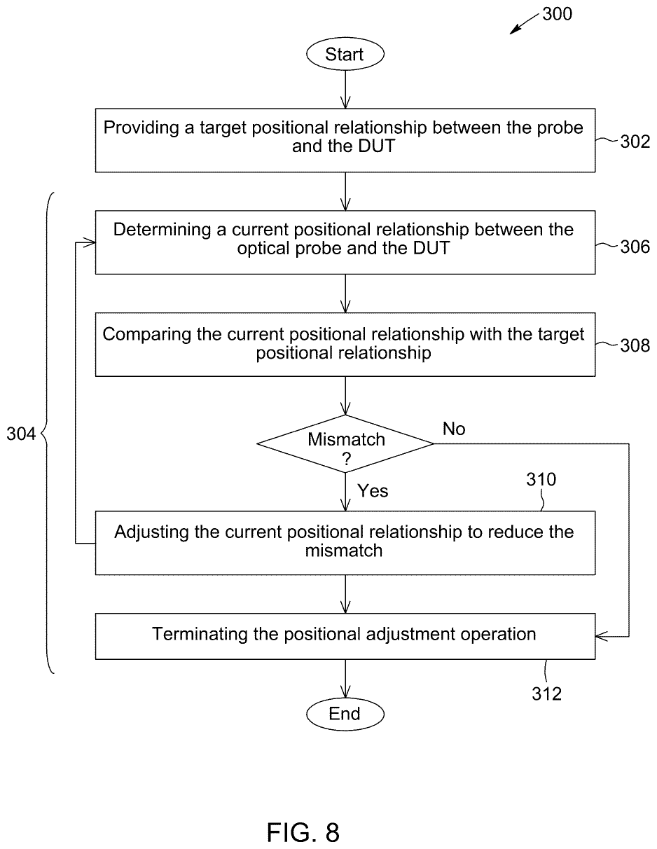

FIG. 8 shows a flow diagram of a method 300 for positional adjustment between an optical probe (e.g., a fiber array) and an optical DUT (e.g., a PIC). The method 300 begins by providing a target positional relationship between the probe and the DUT (step 302). It then proceeds with a positional adjustment operation including one or more iterative cycles (step 304). Each cycle includes: (i) determining the current positional relationship using the disclosed position determination method, such as that shown in FIG. 1 (step 306); (ii) comparing the current positional relationship with the target positional relationship (step 308); and (iii) if a mismatch is detected, adjusting the current positional relationship to reduce the mismatch and initiating another iterative cycle (step 310); otherwise, terminating the positional adjustment operation (step 312). The method 300 may terminate upon achieving an acceptable match (e.g., exact or within a specified tolerance) or upon reaching an end condition (e.g., maximum number of iterations or maximum elapsed time).

The method 300 enables compensation for any detected misalignment or positional offset by incrementally adjusting the probe's position. This feedback-based approach supports closed-loop alignment with high accuracy and repeatability. By continuously refining the probe's position based on interference data, the technique facilitates automation and reduces the impact of positional drift in optical testing environments. Depending on the application, either or both the separation distance and angular orientation between the probe and the DUT can be corrected through this method. By combining both translational and rotational adjustments, the method can achieve high-precision alignment for wafer-level PIC testing and other high-throughput optical characterization applications.

While the embodiments described thus far have focused on edge-coupling configurations, the disclosed methods, where probe positional information is determined from interference patterns in measured reflected spectra, can also be adapted for surface-coupling configurations under appropriate conditions.

Surface couplers are typically grating structures designed to couple light between optical fibers and on-chip waveguides via diffraction, as governed by Bragg's law. In most implementations, these couplers are engineered to emit light at a nonzero angle (commonly between 8° and) 15° to minimize back reflections and optimize coupling efficiency. Due to optical reciprocity, light entering from a fiber follows the same angled path as emitted light, which generally requires angled fiber facets aligned with the grating's optical axis. This geometry avoids the formation of Fabry-Pérot cavities and therefore does not give rise to the spectral interference features leveraged in the above-described position determination technique.

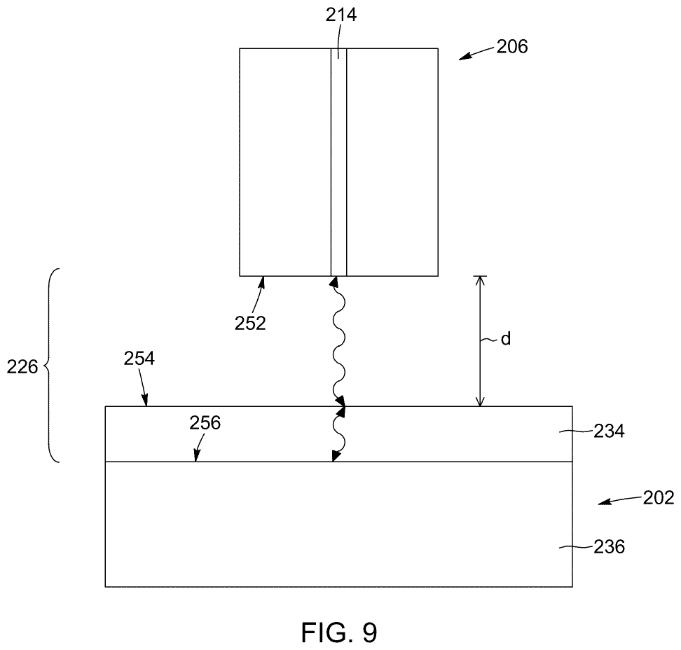

However, when the fiber is not angled and light is delivered at vertical incidence, interference effects can arise that enable position estimation. FIG. 9 illustrates such a configuration, in which an optical probe 206 with a vertically oriented optical channel 214 is positioned above a PIC 202. The PIC 202 includes a top cladding layer 234 and an underlying substrate 236, which in this example are made of silica (SiO₂) and silicon (Si), respectively. The channel 214, in this example, is an optical fiber also made of silica. The probe-to-PIC separation distance d is initially unknown and is to be determined. This arrangement introduces a multi-interface cavity 226 involving three interfaces: (i) a fiber-air interface 252, (ii) an air-silica interface 254, and (iii) a silica-silicon interface 256. Notably, the optical cavity 226 includes not only the air gap between the probe 206 and the PIC 202, but also extends partially into the PIC structure itself. The resulting reflection spectrum includes contributions from all three interfaces, with phase shifts governed by the optical path lengths through the air gap and the cladding layer 234. When the thickness of the cladding layer 234 is known, variations in the interference patterns can be attributed to changes in the phase shift introduced by the air gap, allowing the separation d between the probe 206 and the PIC 202 to be extracted from the measured spectrum. This three-interface configuration can be generalized to an N-interface cavity (N>2), in which the reflection spectrum is modeled using a probe-side interface, a PIC-side interface, and one or more internal optical interfaces within the DUT, consistent with the methods described herein.

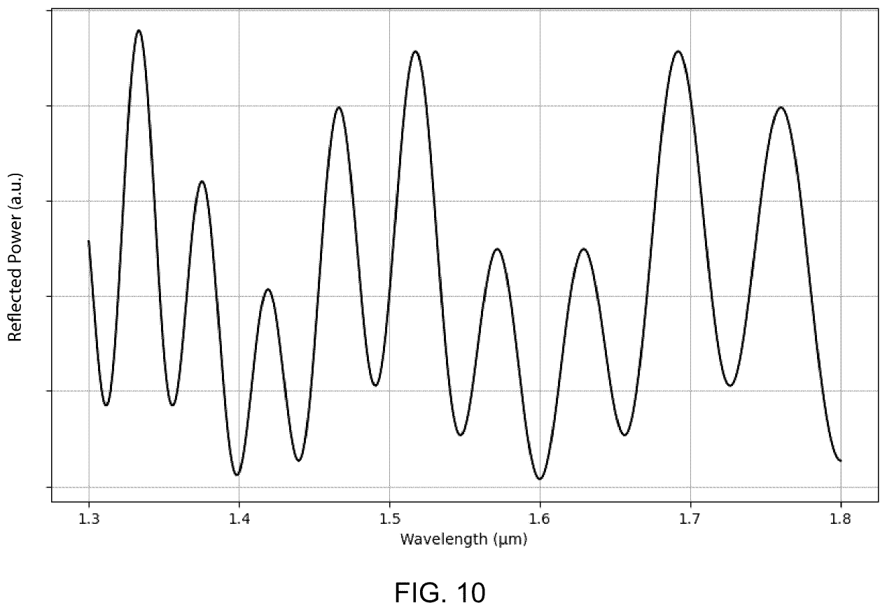

FIG. 10 shows a simulated reflection spectrum for a vertical injection setup with a probe-to-PIC separation distance of 18 μm. The simulation incorporates the known refractive indices of air, silica, and silicon. In contrast to the simpler FP interference patterns observed in two-interface cavities, the resulting spectrum here exhibits more complex features due to multiple reflections and phase accumulations across the three-interface structure. These features may not lend themselves to straightforward analysis via standard FSR techniques commonly used for cavity length estimation. Accordingly, more sophisticated analytical or numerical approaches, such model fitting and Fourier transform analysis, may be required to accurately extract positional information. These techniques may involve applying a model or using calibration data relating reflection spectrum features to known separation distances. For instance, in some embodiments, the vertical separation distance d can be estimated by defining an objective function ƒ(d) that compares the modeled spectral intensity with the measured reflection data:

$$f ( d ) = {\sum }_{i} {[ {I}_{model} ( {λ}_{i} , d ) - {I}_{measured} ( {λ}_{i} ) ]}^{2} . \qquad ( 4 )$$

Simulation results indicate that, when parameters such as refractive indices and layer thicknesses are well characterized, this approach enables high-precision recovery of the probe-to-PIC distance d.

The position determination and adjustment techniques described above can be implemented in conjunction with an optical probe that integrates both positional alignment and optical testing capabilities. As described below, this probe includes two distinct types of optical channels: positioning channels, which are configured to determine the probe's position (i.e., its separation distance and/or angular orientation relative to a DUT), and measurement channels, which are configured to inject light into the DUT and/or collect light from it during optical testing. These channel types differ in their optical interface characteristics and serve complementary roles within the testing system.

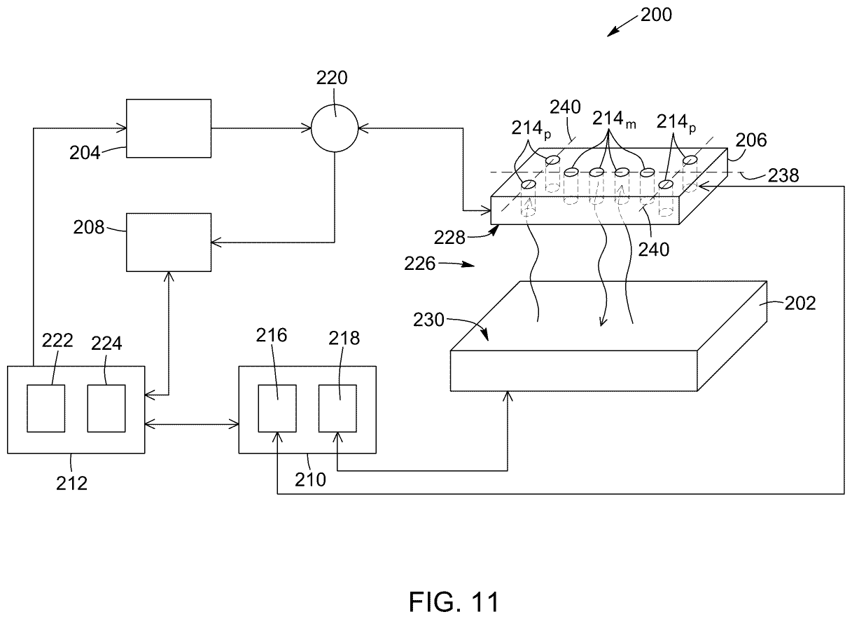

FIG. 11 illustrates another embodiment of a system 200 for testing a DUT 202. As with previously described implementations, the DUT 202 in FIG. 11 is a PIC and is referenced as such below, although the system 200 can also be used to test other types of optical devices. FIG. 11 shows the system 200 configured for surface-coupling to the PIC 202, but edge-coupled arrangements are also possible, as described further below.

The system 200 includes a light source 204, an optical probe 206, an optical detector 208, a positioning assembly 210, and a control and processing unit 212. These components may be generally similar to those described above in connection with the reflection-based positioning techniques and may operate in a similar manner. However, in the system 200 shown in FIG. 11, the probe 206 is specifically designed to enable both position sensing and optical testing, using separate optical channels 214ₚ, 214ₘ configured for each of these respective tasks.

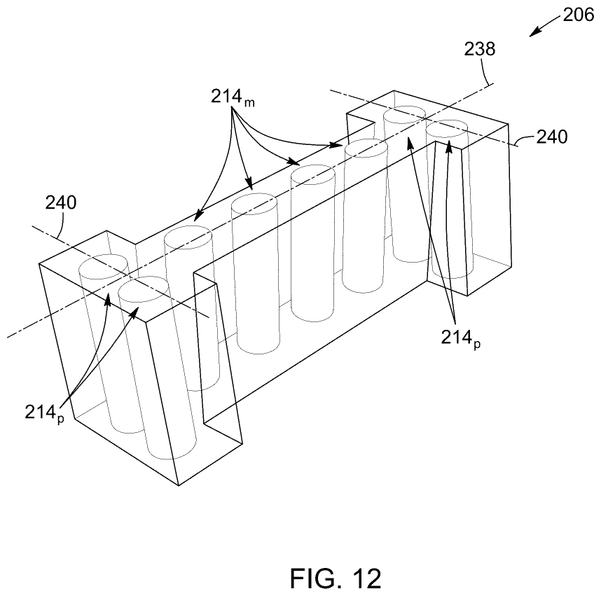

FIG. 12 provides a more detailed view of the probe 206 and its channels 214ₚ, 214ₘ, which include at least one positioning channel 214ₚ and at least one measurement channel 214ₘ. Both types of channels 214ₚ, 214ₘ may be implemented using optical fibers, although other types of waveguides or optical couplers can alternatively be used for either or both channel types. In the illustrated embodiment, the probe 206 includes four positioning channels 214ₚ and four measurement channels 214ₘ, although the number of channels of each type can vary depending on the application, for example, between two and sixteen. The measurement channels 214ₘ are arranged in a linear array along a measurement axis 238. The positioning channels 214ₚ are divided into two groups, one group located at each end of the measurement array. At each end, the two positioning channels 214ₚ are aligned along a positioning axis 240 that is substantially perpendicular to the measurement axis 238, with the midpoint between the two positioning channels 214ₚ coinciding with the measurement axis 238. This layout allows the positioning channels 214ₚ to provide spatially distributed positional feedback. Further detail on the usefulness of this configuration is provided below. However, this is merely one example arrangement, and other configurations may be used depending on probe geometry, packaging constraints, and testing requirements.

Returning to FIG. 11, the positioning channels 214ₚ are configured to form an optical cavity 226 with the PIC 202 upon coupling, such that light reflected from multiple interfaces within the cavity 226 produces interference patterns in a reflection spectrum acquired at those channels 214ₚ. These interference patterns can be analyzed to extract positional information about the positioning channels 214p, including axial separation distance and angular tilt, using techniques as described above. In the illustrated surface-coupling arrangement, cavity formation and resulting interference effects can be achieved by using fibers with flat end facets (i.e., zero-degree cleaved fibers) as the positioning channels 214ₚ. In contrast, the measurement channels 214ₘ are designed to couple light into or out of the PIC 202 via suitable couplers or ports, while avoiding cavity formation and associated reflections. This can be accomplished, for example, by using an angled facet (e.g., between 8° and 15°) or by applying an anti-reflective (AR) coating at the fiber tip of the measurement channels 214ₘ. As noted earlier in connection with the reflection-based positioning techniques, it is further appreciated that the positioning channels 214ₚ do not require alignment with dedicated input structures of the PIC 202. It is sufficient that light from the source 204 reflect off the PIC surface to form the cavity 226, producing interference features in the reflection spectrum R(λ) from which positional information can be extracted.

By separating these functions across different channels, the probe 206 can leverage interference-based feedback for positioning and alignment without compromising the quality of the measurement signal during testing. This dual-channel approach enables the system 200 to operate in either a positioning mode or a measurement mode. In the positioning mode, the light source 204 and the optical detector 208 are used to acquire reflection spectra via the positioning channels 214ₚ. The control and processing unit 212 analyzes the interference patterns in these spectra to determine the positional relationship (i.e., separation distance and/or orientation) between the positioning channels 214ₚ and the PIC 202. Based on this information and the known spatial offsets between the positioning and measurement channels 214p, 214ₘ, the control and processing unit 212 operates the positioning assembly 210 to bring the measurement channels 214ₘ into a desired measurement position relative to the PIC 202. In other words, the known channel offsets, determined by the probe's design, enable accurate alignment of the measurement channels 214ₘ based on the positional feedback obtained from the positioning channels 214ₚ.

The specific channel layout shown in FIG. 12, with the positioning channels 214ₚ arranged symmetrically around the measurement channels 214ₘ, offers several advantages. For example, if the reflection spectra from the positioning channels 214ₚ at both ends of the probe 206 (i.e., at the four corners) indicate that these channels are equidistant from the PIC 202, it can be inferred that the measurement channels 214ₘ are positioned at the intended coupling angle (e.g., between 8° and 15° for common angled-cleaved fibers) relative to the top surface of the PIC 202. This symmetry-based alignment strategy enhances angular precision by placing the positioning channels 214ₚ farther from the centroid of the measurement channel array, thereby increasing sensitivity to angular misalignment and facilitating corrective adjustments. This design also provides practical assembly benefits. The probe 206 can be fabricated by combining different commercially available fiber arrays (e.g., two non-cleaved arrays for the positioning channels 214ₚ and one angled-cleaved array for the measurement channels 214ₘ) into a single integrated structure, as shown in FIG. 12. The use of off-the-shelf components in a custom configuration supports scalable probe designs while achieving the desired optical performance.

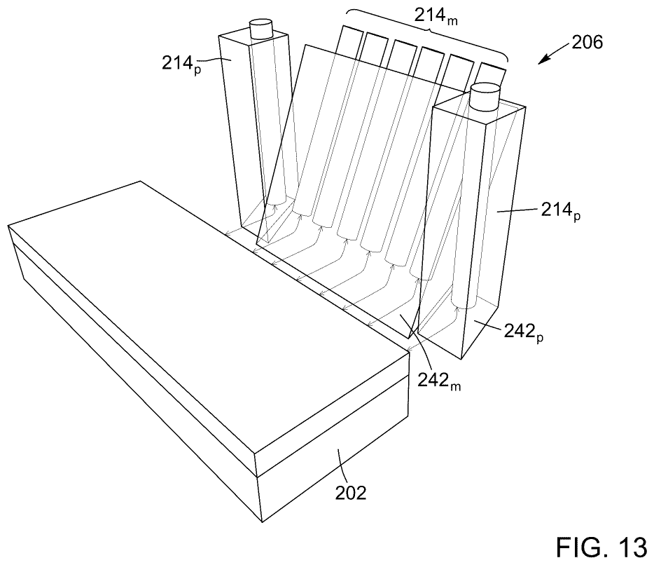

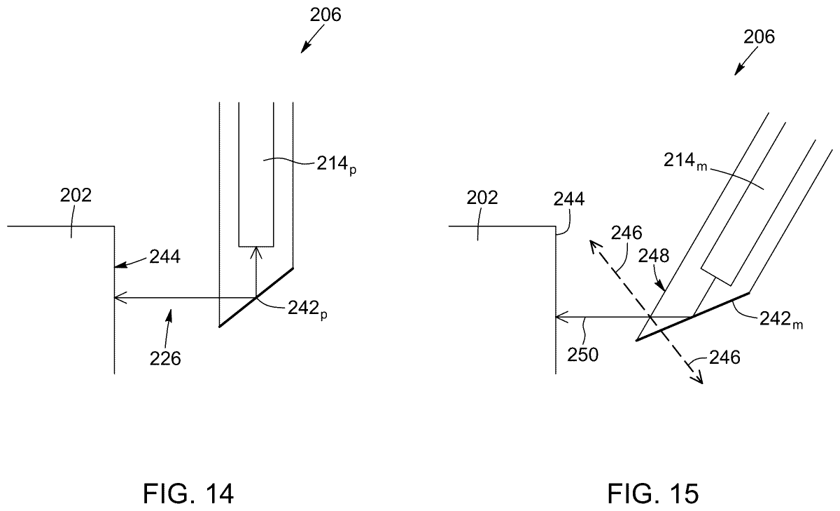

Probe configurations for edge-coupled testing are also possible, as illustrated in FIG. 13. In this embodiment, the probe 206 may incorporate reflective structures 242p, 242ₘ, such as mirrors or total internal reflection surfaces, configured to redirect light between the positioning and measurement channels 214ₚ, 214ₘ within the probe 206 and the vertically oriented PIC edges. As with surface-coupled arrangements, the positioning channels 214ₚ are configured to promote cavity formation, while the measurement channels 214ₘ are configured to suppress it. As shown in FIG. 14, the positioning channels 214ₚ may include vertically oriented non-cleaved fibers coupled to a reflective structure 242ₚ oriented at approximately 45°, which redirects the incident light along a horizontal path that impinges normally on the PIC edge 244. Reflected light from the PIC 202 follows the same path in reverse, enabling the formation of an optical cavity 226 and resulting in interference patterns in the reflection spectrum, from which probe positional information can be extracted. In contrast, the measurement channels 214ₘ, as depicted in FIG. 15, may use obliquely oriented, non-cleaved fibers. In this configuration, the reflective structure 242ₘ is suitably oriented to ensure that light is directed normally onto the PIC edge and collected along the same path. However, cavity formation is avoided due to the oblique orientation of the measurement channels 214ₘ relative to the PIC edge 244, thereby directing parasitic reflections 246 at the channel surface 248 away from the testing optical path 250. This spatial and optical separation of functionalities between the positioning channels 214ₚ and the measurement channels 214ₘ supports both accurate positioning and reliable signal acquisition, even in deep-trench or limited-access edge-coupled scenarios.

Additional probe geometries and coupling strategies can be envisioned to address varying testing conditions and device layouts. For instance, rather than using a single angled surface, a probe may incorporate multiple angled facets arranged in a stepped or segmented configuration. Such designs can provide tailored reflection control across different fiber channels. Another possible configuration includes slightly curved or wedge-shaped surfaces that redirect or scatter reflections away from the fiber inputs, thereby reducing FP interference and potentially serving additional optical functions such as beam shaping or focusing.

Overall, the custom probe design disclosed herein can enhance testing functionality by separating the optical roles of positioning and measurement into distinct channels provided within a single integrated configuration. This dual-function architecture enables high-precision alignment without compromising the optical signal quality required for accurate and repeatable testing.

In the present description, similar features in the drawings have been given similar reference numerals. To avoid cluttering certain figures, some elements may not be indicated if they were already identified in a preceding figure. The elements of the drawings are not necessarily depicted to scale since emphasis is placed on clearly illustrating the elements and structures of the present embodiments. Positional descriptors indicating the location and/or orientation of one element with respect to another element are used herein for ease and clarity of description. Unless otherwise indicated, these positional descriptors should be taken in the context of the figures and should not be considered limiting. In particular, positional descriptors are intended to encompass different orientations in the use or operation of the present embodiments, in addition to the orientations exemplified in the figures. Furthermore, when a first element is referred to as being “on”, “above”, “below”, “over”, or “under” a second element, the first element can be either directly or indirectly on, above, below, over, or under the second element, respectively, such that one or multiple intervening elements may be disposed between the first element and the second element.

The terms “a”, “an”, and “one” are defined herein to mean “at least one”, that is, these terms do not exclude a plural number of elements, unless stated otherwise.

The term “or” is defined as “and/or”, unless stated otherwise.

Terms such as “substantially”, “generally”, and “about”, which modify a value, condition, or characteristic should be understood to mean that the value, condition, or characteristic falls within acceptable tolerances for the proper functioning of the described embodiment or within an acceptable range of experimental error. In particular, the term “about” generally denotes a range of values that one skilled in the art would consider equivalent to the stated value (e.g., having the same or an equivalent function or result). In some instances, the term “about” means a variation of +10% of the stated value. It is noted that all numeric values used herein are assumed to be modified by the term “about”, unless stated otherwise. The term “between” refers to a range defined by endpoints, inclusive of both endpoints, unless stated otherwise.

The term “based on” as used herein is intended to mean “based at least in part on”, whether directly or indirectly, and to encompass both “based solely on” and “based partly on”. In particular, the term “based on” may also be understood as meaning “from”, “depending on”, “representative of”, “indicative of”, “associated with”, “relating to”, and the like.

The terms “match”, “matching”, and “matched” refer herein to a condition where two elements are either identical or within a predetermined tolerance of each other. These terms encompass not only exact matches but also substantial, approximate, or subjective matches, as well as a best or highest match among various matching possibilities.

The terms “connected” and “coupled”, along with their derivatives and variants, refer herein to any form of connection or coupling, whether direct or indirect, between two or more elements, unless stated otherwise. This connection or coupling can take various forms, including, but not limited to, mechanical, optical, electrical, magnetic, thermal, chemical, logical, fluidic, operational, or any combination thereof.

The term “concurrently” refers herein to the simultaneous or overlapping occurrence of two or more processes. The term “concurrently” does not necessarily imply complete synchronicity but encompasses various scenarios. These scenarios include the simultaneous occurrence of two processes; a first process that both begins and ends during the duration of a second process; and a first process that starts during the duration of a second process but ends after the second process is completed.

The term “measured” when referring to a quantity or parameter is intended to mean that the quantity or parameter can be measured either directly or indirectly. In the case of indirect measurement, the quantity or parameter can be derived, retrieved, inferred or otherwise determined from directly measured data.

The terms “light” and “optical”, along with their variants and derivatives, encompass radiation across any appropriate region of the electromagnetic spectrum. This includes not only visible light but also extends to invisible regions such as the terahertz (THz), infrared (IR), and ultraviolet (UV) spectral bands. Furthermore, all descriptions provided herein as a function of wavelength could also be formulated as a function of frequency, wave number, energy, or other pertinent spectral parameters.

The term “processor” as used herein broadly refers to any electronic device, circuitry, or component capable of processing, receiving, or transmitting data or instructions, such as computer programs, commands, functions, processes, software codes, executables, applications, and similar entities. The term “processor” is meant to encompass a single processor or processing unit, multiple processors or processing units, or other suitably configured processing elements. When a processor includes multiple processing elements, the processing elements may be located at a single site or distributed across multiple sites interconnected by a communication network. Examples of communication networks include local area networks (LANs) and wide area networks (WANs) such as the Internet. Non-limiting examples of processors include general-purpose single- or multi-core processors; central processing units (CPUs); microprocessors; controllers; microcontrollers; digital signal processors (DSPs); programmable logic devices; a field-programmable gate arrays (FPGAs); application-specific integrated circuits (ASICs); digital processors or circuits; analog processors or circuits; state machines; and/or any other device capable of processing information.

The term “memory” as used herein broadly refers to any electronic device, circuitry, or component capable of storing electronic data or information. In some instances, the term “memory” may be used interchangeably with the term “computer readable storage medium”. The term “memory” is meant to encompass a single memory or memory unit, multiple memories or memory units, or other suitably configured memory elements. When a memory includes multiple memory elements, these elements may be located at a single site or distributed across multiple sites interconnected by a communication network. Non-limiting examples of memories include random-access memories (RAM) of any type; read-only memories (ROM) of any type; magnetic storage devices; optical storage devices; solid-state drive (SSD) devices, such as flash drive memories; and any other tangible and/or non-transitory computer readable medium capable of storing electronic data or information.

Numerous modifications could be made to the embodiments described above without departing from the scope of the appended claims.

1. A method for determining a positional relationship between an optical probe and an optical device under test (DUT), the method comprising:
positioning the optical probe relative to the DUT with a separation distance therebetween, the separation distance spanning at least a portion of an optical cavity formed between the optical probe and the DUT, the optical cavity comprising multiple optical interfaces;
delivering probe light to the DUT via the optical probe;
collecting return light reflected from the optical cavity via the optical probe;
detecting the collected return light to obtain a reflection spectrum comprising interference patterns resulting from reflections at the multiple optical interfaces of the optical cavity; and
analyzing the reflection spectrum to determine the separation distance based on the interference patterns.

2. The method of claim 1, wherein the DUT comprises a photonic integrated circuit.

3. The method of claim 1, wherein the optical probe comprises one or more optical fibers.

4. The method of claim 1, wherein positioning the optical probe relative to the DUT comprises coupling the optical probe to the DUT in an edge-coupled configuration.

5. The method of claim 1, wherein positioning the optical probe relative to the DUT comprises coupling the optical probe to the DUT in a surface-coupled configuration.

6. The method of claim 1, wherein the reflection spectrum is acquired within a wavelength range from about 1260 nm to about 1680 nm.

7. The method of claim 1, wherein analyzing the reflection spectrum comprises:
extracting a free spectral range (FSR) parameter from the reflection spectrum; and
determining the separation distance based on the FSR parameter.

8. The method of claim 1, wherein analyzing the reflection spectrum comprises modeling the optical cavity as a two-interface structure, the multiple optical interfaces comprising a probe-side interface between the optical probe and a separation medium between the optical probe and the DUT, and a DUT-side interface between the DUT and the separation medium.

9. The method of claim 1, wherein analyzing the reflection spectrum comprises modeling the optical cavity as an N-interface structure, with N>2, the multiple optical interfaces comprising a probe-side interface between the optical probe and a separation medium between the optical probe and the DUT, a DUT-side interface between the DUT and the separation medium, and at least one internal optical interface within the DUT.

10. The method of claim 1, wherein the optical probe comprises a set of optical channels having known positional offsets therebetween, and the method further comprises:
performing the delivering, collecting, detecting, and analyzing steps for each of the optical channels to obtain a corresponding set of separation distances; and
determining an angular position of the optical probe relative to the DUT based on the set of separation distances and the known positional offsets.

11. The method of claim 10, wherein the DUT is arranged on a planar substrate, the set of separation distances extending substantially parallel to the planar substrate, and the angular position is defined with respect to a rotation axis substantially perpendicular to the planar substrate.

12. A method for positional adjustment between an optical probe and an optical device under test (DUT), the method comprising:
providing a target positional relationship between the optical probe and the DUT; and
performing a positional adjustment operation comprising one or more iterative cycles, each iterative cycle comprising:
determining, using the method of claim 1, a current positional relationship between the optical probe and the DUT;
comparing the current positional relationship with the target positional relationship; and
when a mismatch exists between the current and target positional relationships, adjusting the current positional relationship to reduce the mismatch and initiating another iterative cycle; otherwise, terminating the positional adjustment operation.

13. The method of claim 12, wherein the target positional relationship includes a target separation distance and/or a target angular orientation of the optical probe relative to the DUT.

14. A system for determining probe positioning relative to optical device under test (DUT), the system comprising:
a light source configured to generate probe light;
an optical probe configured to be positioned relative to the DUT with a separation distance therebetween, the separation distance spanning at least a portion of an optical cavity formed between the optical probe and the DUT, the optical cavity comprising multiple optical interfaces, the optical probe being configured to couple the probe light from the light source into the DUT and to collect return light reflected from the optical cavity;
an optical detector configured to detect the collected return light as a reflection spectrum comprising interference patterns resulting from reflections at the multiple optical interfaces of the optical cavity; and
a control and processing unit coupled to the optical detector and configured to analyze the reflection spectrum to determine the separation distance based on the interference patterns.

15. The system of claim 14, wherein the light source comprises a wavelength-swept light source.

16. The system of claim 14, wherein the light source comprises a broadband light source.

17. The system of claim 14, wherein the optical probe comprises one or more optical fibers.

18. The system of claim 14, wherein the optical probe is configured to couple with the DUT in an edge-coupled configuration.

19. The system of claim 14, wherein the optical probe is configured to couple with the DUT in a surface-coupled configuration.

20. The system of claim 14, wherein the optical probe comprises a set of optical channels having known positional offsets therebetween, the light source and the optical detector being configured to acquire, through each optical channel, a corresponding one of a set of reflection spectra, and wherein the control and processing unit is configured to: analyze the set of reflection spectra to determine a corresponding set of separation distance; and determine an angular position of the optical probe relative to the DUT based on the set of separation distances and the known positional offsets.
